(19) United States
(12) Patent Application Publication
(10) Pub. No.: US 2013/0089942 A1
(43) Pub. Date: Apr. 11, 2013

(54) METHOD FOR PRODUCING A SOLAR CELL

(71) Applicant: Tim Boescke, Erfurt (DE)

(72) Inventor: Tim Boescke, Erfurt (DE)

(21) Appl. No.: 13/640,165

(22) PCT Filed: Feb. 16, 2011
(86) PCT No.: PCT/EP11/52257

§ 371 Date: Dec. 19, 2012

(30) Foreign Application Priority Data
Apr. 9, 2010 (DE) 10 2010 003 784.2

(51) Int. Cl. H01L 31/18

(52) U.S. Cl. CPC H01L 31/1804
USPC 438/57

(57) ABSTRACT

A method for producing a solar cell from a silicon substrate, which has a first main surface, used in normal application as an incident light side and a second main surface, used as the back surface, having a passivating layer on the second main surface, includes the steps: applying an oxygen-containing layer onto the second main surface of the silicon substrate, and heating the silicon substrate to a temperature of at least 800° C. to densify the oxide-containing layer and for the oxidation of the boundary surface between the oxide-containing layer and the second main surface of the silicon substrate to form a thermal oxide, an oxygen source giving off oxygen for the oxidation.

### CROSS REFERENCE TO RELATED APPLICATIONS

The present application is the national stage entry of International Patent Application No. PCT/EP2011/052257, filed on Feb. 16, 2011, which claims priority to Application No. DE 10 2010 003 784.2, filed in the Federal Republic of Germany on Apr. 9, 2010.

### FIELD OF INVENTION

The present invention relates to a method for producing a solar cell from a silicon substrate.

### BACKGROUND INFORMATION

Solar cells are mostly made up of a silicon substrate. In order to ensure the long term stability of solar cells and to prevent the penetration of foreign atoms into the substrate, the solar cells are provided with a passivating layer.

Up to now, dielectric thin films have been used for the passivation of the silicon surfaces of solar cells. In industrial practice, above all, silicon nitride films deposited using a plasma method have prevailed. It is known, however, that thermally grown silicon oxide layers have clearly better passivating properties. This is above all the case in the passivation of p-doped surfaces, since in this case, high positive charges in silicon nitride have an effect on lowering performance (generation of an inversion layer and “parasitic shunting”). In particular for the passivation of the back surfaces of PERC (passivated emitter, and rear cell)-cells, PERT (passivated emitter, rear totally diffused)-cells, and PERL (passivated emitter, rear locally diffused)-cells, the use of thermal oxide is therefore desirable.

In the methods known up to the present, for producing thermal oxides in solar cell manufacturing, there are many disadvantages. For example, the process takes a very long time, since the processing time increases quadratically with the layer thickness, which leads to high processing costs. In addition, the process requires a high thermal budget, which may change the diffusion profile disadvantageously. It is also a disadvantage that the process is inherently two-sided. Since, however, the passivating layer is typically only required on one side of the solar cell, the other side of the solar cell has to be masked.

For PERC cells, a process is known, for example, from L. Gautero et al., “All-Screen-Printed 120-μm-Thin Large Area Silicon Solar Cells Applying Dielectric Rear Passivation and Laser-Fired Contacts Reaching 18% Efficiency,” 24th EU-PVSEC 2009, Hamburg, Session 2DO.2.5, which, briefly summarized, includes the following steps:
1.) texture
2.) scrubbing (HNO₃)
3.) diffusion of POCl₃ with drive-in step
4.) etching away of PSG (phosphorus silicate glass)
5.) SiN depositing on front side
6.) emitter distance back surface
7.) scrubbing standard cleaning 1/standard cleaning 2
8.) oxidation
9.) SiO₂ depositing back surface
10.) SiN depositing back surface

In this case, the one-sidedness of the oxidation is achieved by front side masking with deposited SiN. In order to reduce the processing time, only a thin layer (˜20 nm) of oxide is grown on, and this is subsequently thickened by deposited oxide or nitride. Since, for passivation, primarily the boundary surface between SiO₂ and Si is relevant, because of the layer stack, a passivation quality comparable to pure thermal oxide is attained. It is disadvantageous however that the method is technically demanding and costly.

### SUMMARY

According to the present invention, a method for producing a solar cell from a silicon substrate, which has a first main surface, used in normal application as an incident light side and a second main surface, used as the back surface, having a passivating layer on the second main surface, includes the following steps: applying an oxygen-containing layer onto the second main surface of the silicon substrate; and heating the silicon substrate to a temperature of at least 800° C. to densify the oxide-containing layer and for the oxidation of the boundary surface between the oxide-containing layer and the second main surface of the silicon substrate to form thermal oxide, an oxygen source giving off oxygen for the oxidation. Advantageously, the method according to the present invention is technically simple and cost-effective.

A process atmosphere of the silicon substrate, particularly including O₂ and/or H₂O, may function as an oxygen source. The oxide-containing layer, particularly including SiO₂, ZrO₂, SiOₐN_{b} and/or SiOₐC_{b}, where each b<<a, may be applied in such a way that it is permeable to oxygen. Advantageously, the method is technically simplified further and becomes more cost-effective.

The oxide-containing layer, particularly including SiO₂, may be applied by a CVD or a PECVD method, especially using SiH₄, onto the second main surface of the silicon substrate. The costs of the method are thereby lowered further, since the CVD as well as the PECVD methods are very cost-effective. In addition, the oxide-containing layer is applied uniformly onto the second main surface.

The oxide-containing layer may include an hyperstoichiometric oxide, particularly SiO₂₊ₓ:H and/or an oxide having lower density and/or an hygroscopic oxide, preferably BSG, PSG and/or TEOS oxide and the oxide-containing layer may function as the oxygen source. This further simplifies the method technically, since no additional oxygen source is required.

Furthermore, in the method, a silicon oxide layer created during the heating of the silicon substrate may be etched away from the first main surface, and a part of the oxide-containing layer may be etched away from the second main surface. Advantageously, the silicon substrate is exposed, in a simple manner, on the first main surface, while the passivating layer is only partially removed on the second main surface.

Moreover, in the method, after the application of the oxide-containing layer, a doping agent, particularly boron, preferably using boron tribromide, and/or phosphorus, preferably using phosphorus oxychloride may be diffused in, the doping agent being diffused into the first main surface during the step of heating the silicon substrate, and the oxide-containing layer functioning as masking layer of the second main surface during the heating. By doing this, in a simple manner a doped layer may be formed on the first main surface of the silicon substrate, which is able to function as an emitter, while the doping agent does not diffuse into the second main surface of the silicon substrate.

Doping agent-silicon compound layers created during the heating of the silicon substrate may be etched away from the first main surface and/or the second main surface. Advantageously, the silicon of the silicon substrate is exposed on the first main surface, and the oxide-containing layer is exposed on the second main surface.

In the method, furthermore, before the application of the oxide-containing layer, a surface patterning may be applied to the first main surface and/or the second main surface. Advantageously, specifically no oxide-containing layer is able to be applied on parts of the first and/or second main surface.

Furthermore, in the method, the second main surface may be planarized before the oxide-containing layer is applied. By doing this, the application of the oxide-containing layer on the second main surface is clearly improved. Moreover, in the proposed method, the first main surface and/or the second main surface may be scrubbed before the oxide-containing layer is applied, particularly using HNO₃. Advantageously, the application of the oxide-containing layer is further improved.

In the method, furthermore boron or phosphorus, for generating a back-surface-field (BSF) layer, may be diffused into the second main surface or implanted by ion implantation, which is activated during the heating of the silicon substrate. The efficiency of the solar cell is improved by the back-surface-field, since the back-surface-field represents a barrier for the electrons, which therefore obtain no access to the surface of the silicon substrate.

Also in the method, a SiN antireflection layer may be applied to the first main surface and/or to the oxide-containing layer of the second main surface. Because of the antireflection layer, less light is reflected from the silicon substrate, whereby more light penetrates into the silicon substrate. This increases the efficiency of the solar cell.

Furthermore, before the application of the oxide-containing layer, one or more holes may be produced by a laser through the silicon substrate to connect the first main surface to the second main surface, particularly using a laser. Advantageously, because of the holes, an electrical connection may be formed in a simple manner from the first main surface to the second main surface, and vice versa.

Before the application of the oxide-containing layer, in the method, the following method steps may be carried out: a doping agent, particularly boron, preferably using boron tribromide, and/or phosphorus, preferably using phosphorus oxychloride, are diffused into both main surfaces; the doping agent is diffused into the silicon substrate, by heating the silicon substrate, to form an emitter layer on the first main surface and an emitter layer on the second main surface; doping agent-silicon compounds created by heating the silicon substrate are etched away from the first main surface and/or the second main surface; a masking layer, preferably using SiN, is applied to the first main surface; and the emitter layer of the second main surface is removed, especially by etching, the SiN layer functioning as masking layer of the first main surface during the removal. Advantageously, compared to the related art, the step of scrubbing the silicon substrate, that is, standard cleaning 1/standard cleaning 2 is, or may be omitted. This saves time and costs, and the process is simplified technically.

Further advantages and advantageous refinements of the present invention are illustrated in the drawings and elucidated in the following description of exemplary embodiments. It should be noted that the drawings have only a descriptive character and are not intended to limit the present invention in any form.

### BRIEF DESCRIPTION OF THE DRAWINGS

FIGS. 1a to 1d illustrate a silicon substrate after successive steps of an exemplary method according to the present invention for producing a solar cell from a silicon substrate having a passivating layer.

FIGS. 2a to 2d illustrate a silicon substrate after successive steps of an additional, exemplary method according to the present invention for producing a solar cell from a silicon substrate having a passivating layer.

FIGS. 3a to 3d illustrate a silicon substrate after successive steps of an additional, exemplary method according to the present invention for producing a solar cell from a silicon substrate having a passivating layer.

In the subsequent description, the same reference numerals are used for the same and similarly acting parts.

### DETAILED DESCRIPTION

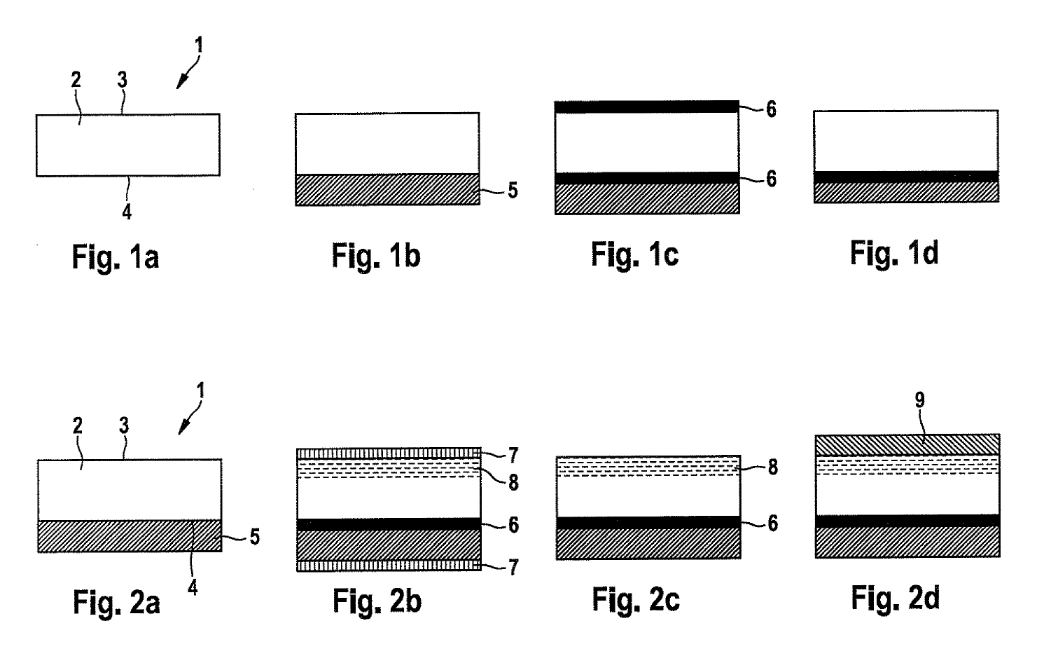

FIGS. 1a to 1d show a silicon substrate 1, each after steps of an exemplary method according to the present invention, for producing a solar cell from a silicon substrate having a passivating layer on the back surface of the substrate. FIG. 1a shows a silicon wafer or a silicon substrate 1. Silicon substrate 1 is made of crystalline silicon 2 and has a first main surface 3, also called front side, and a second main surface 4, also called back surface, which is opposite first main surface 3. Figure lb shows silicon substrate 1 after the first method step. In the first method step, silicon dioxide is applied to second main surface 4 of silicon substrate 1 by a PECVD method. Instead of the silicon dioxide, other oxide-containing layers are conceivable. Other methods for applying the layer are also conceivable.

Silicon substrate 1 is heated in a second method step to a temperature of at least 800° C. This densifies oxide-containing layer 5 and the boundary layer between oxide-containing layer 5 and silicon 2 of silicon substrate 1 is (re)oxidized. Because of this, at the boundary layer, a thin layer is created of top-grade thermal oxide, which has good passivating properties. The process atmosphere of silicon substrate 1 is able to be the oxygen source (e.g., O₂ or H₂O). In this context, the deposited oxide-containing layer 5 is permeable to oxygen, which is the case, for instance, with SiO₂ and SiOₐN_{b} or SiOₐC_{b}, when b is much smaller than a.

Also conceivable as an oxide-containing layer are other oxygen-conducting metal oxides, such as ZrO₂.

Oxide-containing layer 5 itself may also be the oxygen source.

In this case, an over-stoichiometric oxide is applied to second main surface 4 of silicon substrate 1 as the oxide-containing layer. During the heating of the silicon substrate, the over-stoichiometric oxide gives off water and/or oxygen. The over-stoichiometric oxide may be SiO₂₊ₓ:H, for example, or even a hygroscopic oxide, such as BSG, PSG, or TEOS oxide. In addition, an oxide having a low density is usable to simplify the oxygen diffusion. This is typically the case in SiH₄ processes at low temperatures.

An amorphous SiO₂ layer is produced on the silicon substrate by using SiH₄ and an oxygen source, using a PECVD method. As the oxygen source for this, laughing gas may be used, or pure oxygen.

SiH₄ processes run at temperatures between room temperature and ca. 500° C., preferably at a temperature around 200° C.

FIG. 1b shows silicon substrate 1 after being heated. On first main surface 3 a silicon dioxide layer 6 has formed. On the opposite second main surface 4, a thermal oxide 6 has formed at the boundary surface between the silicon 2 and the oxide-containing layer 5.

A one-sided oxide, i.e., a solar cell having a passivation layer on only one side of silicon 2, is now formed by etching the two main surfaces 3, 4. The silicon dioxide layer is removed on first main surface 3 of silicon substrate 1 by the etching. On second main surface 4, only a part of oxide-containing layer 5 is removed by the etching. Consequently, a solar cell is produced which includes a passivating layer having a top-grade thermal oxide 6 on only one side, namely on the back surface.

In FIGS. 2a to 2d, a silicon substrate 1 is shown after successive steps of an additional, exemplary method according to the present invention, for producing a solar cell having a passivating layer on the back surface. In FIG. 2a, onto a silicon substrate 1 which includes a wafer of silicon 2, an oxide-containing layer 5 has already been applied onto second main surface 4, which is opposite to first main surface 3. In a second method step, phosphorus is diffused in. PSG 7, phosphosilicate glass, forms in this process, on first main surface 3 of silicon substrate 1, and on silicon dioxide 5 on second main surface 4.

The phosphorus that has diffused in is driven into silicon 2 of silicon substrate 1 by heating, so as to form an emitter 8 on first main surface 3 of silicon substrate 1. During this drive-in step, a thermal oxide layer 6 is created at the boundary surface between silicon 2 and silicon dioxide 5 applied to second main surface 4 of silicon substrate 1. The state of the layer sequence after this method step is shown in FIG. 2b.

PSG 7 is removed from the two main surfaces 3, 4 by etching first main surface 3 and second main surface 4. FIG. 2c shows the result after the etching of the two main surfaces 3, 4. On first main surface 3, silicon 2 is now exposed, and it includes a thin layer 8 doped with phosphorus. On second main surface 4 of silicon substrate 1, thermal oxide 6 is located, and on this there is a layer of silicon dioxide 5. FIG. 2c shows the state of silicon substrate 1 after this method step.

In an additional method step, a SiN antireflection layer 9 is now applied onto first main surface 3 of silicon substrate 1. FIG. 2d shows silicon substrate 1 after the end of the method. Silicon substrate 1 has a passivating layer on only the back surface, which includes a thermal oxide 6.

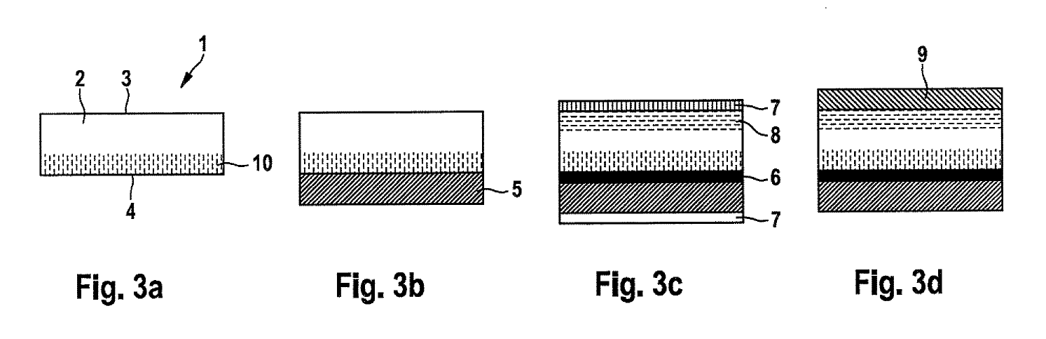

In FIGS. 3a to 3d, a silicon substrate 1 is shown after successive steps of an additional, exemplary method according to the present invention, for producing a solar cell having a passivating layer on one side of silicon substrate 1. In a first step, a boron layer 10 is applied to second main surface 4 of silicon substrate 1 as a back-surface-field, for instance, by diffusion. Silicon substrate 1 is shown in FIG. 3a after this first step.

A silicon dioxide layer 5 is now applied onto second main surface 4 of silicon substrate 1. After this step, the layer sequence is shown in FIG. 3b.

Phosphorus is now diffused in to form an emitter 8. Thereby PSG 7 is formed on first main surface 3 and on silicon dioxide 5 on second main surface 4. During the drive-in step of the phosphorus into silicon 2, at the boundary layer, between silicon 2 and silicon dioxide 5 applied onto second main surface 4, a thermal oxide layer 6 is created. In addition, because of the thermal step of heating silicon substrate 1, the boron of boron layer 10 is activated, and damage from the implantation steps is annealed out. Silicon substrate 1 is shown in FIG. 3c after this method step.

PSG 7 is now removed from the two main surfaces 3, 4 by etching first main surface 3 and second main surface 4. In a last method step, a SiN antireflection layer 9 is now applied onto first main surface 3 of silicon substrate 1, as shown in FIG. 3d.

The exemplary method described here may be combined with the previously named process, whereby the process flow is considerably simplified, since an additional oxidation step is no longer required, and the number of scrubbing steps is reduced. In addition, because of the exemplary method according to the present invention, in combination with the previously known process flow, the required oxidation time/oxidation temperature may be reduced.

An exemplary, modified process according to the present invention includes:
1.) texture
2.) scrubbing (HNO₃)
3.) diffusion of POCl₃ with drive-in step
4.) etching away of PSG
5.) SiN depositing on front side
6.) emitter removal RS
7.) SiO₂ depositing back surface
8.) oxidation
9.) SiN depositing back surface

Compared to the process according to the related art, steps 8 and 9 (now steps 8 and 7) are exchanged. Step 7 of the previously known Sinto process, that is, the standard cleaning 1/standard cleaning 2 process for removing metal contamination, which is costly and technically demanding, is omitted or may be omitted.

The PERC cell produced by this process may be expanded to a PERT cell using a boron implant. In this case, the POCl₃/BBr₃ diffusion in addition fulfills the function of activating the implanted dose, so that overall two high-temperature steps may be saved.

An exemplary, new PERC process according to the present invention includes:
1.) texture (+back surface planarization)
2.) scrubbing (HNO₃, possibly more)
3.) SiO:H deposition back surface
4.) diffusion of POCl₃ with drive-in step
5.) etching away of PSG
6.) SiN depositing on front side
7.) SiN depositing back surface

Because of this new PERC process, an additional oxidation step is saved.

In addition, this method may be combined with an MWT (metal wrap through) process flow.

An exemplary, new PERC-MWT process according to the present invention includes:
1.) texture (+ back surface planarization)
2.) scrubbing
3.) SiO:H deposition back surface
4.) produce laser holes (+ possibly ablation of back surface in the bus bar area)
5.) diffusion of POCl₃ with drive-in step
6.) removal of PSG
7.) SiN depositing on front side
8.) SiN depositing back surface

An exemplary, new PERT process having ion implantation according to the present invention includes:
1.) texture (+ back surface planarization)
2.) scrubbing
3.) implantation BSE (phosphorus or boron)
4.) SiO:H deposition back surface
5.) diffusion of BBr₃ or POCl₃ with drive-in step
6.) etching away of PSG
7.) SiN depositing front side
8.) SiN depositing back surface

Since POCl₃ or BBr₃ diffusion or the drive-in step simultaneously has the effect of activating of the boron implantation, two high-temperature steps are saved in this case.

The process flows suggested are also applicable without restriction to a cell process flow having selective front side diffusion. In this context, the quality of the back surface passivation may even be improved by a long drive-in step of the front side diffusion.

At this point it should be mentioned that all the abovementioned steps of the method, by themselves and in any combination, particularly the details shown in the drawings, are included within the scope of the present invention, including any modifications within the skill of one of ordinary skill in the art.

Incidentally, the execution of the method is not restricted to the above-mentioned examples and emphasized aspects.

1-15. (canceled)

16. A method for producing a solar cell from a silicon substrate, which has a first main surface used in normal application as an incident light side, and a second main surface used as a back surface, the second main surface having a passivating layer thereon, the method comprising:
applying an oxide-containing layer to the second main surface (4) of the silicon substrate; and
heating the silicon substrate to a temperature of at least 800° C. to density the oxide-containing layer and for oxidation of a boundary surface between the oxide-containing layer and the second main surface of the silicon substrate to form a thermal oxide, an oxygen source giving off oxygen for the oxidation.

17. The method according to claim 16, wherein a process atmosphere including at least one of O₂ and H₂O functions as the oxygen source.

18. The method according to claim 16, wherein the oxide-containing layer includes at least one of SiO₂, ZrO₂, SiOₐN_{b} and SiOₐC_{b}, and is permeable to oxygen, where each b<<a.

19. The method according to claim 16, wherein the oxide-containing layer includes SiO₂, and is applied onto the second main surface of the silicon substrate by a CVD method or a PECVD method by using SiH₄.

20. The method according to claim 16, wherein the oxide-containing layer includes at least one of a hyperstoichiometric oxide, SiO₂₊ₓ:H, an oxide having lower density, a hygroscopic oxide, BSG, PSG and TEOS oxide, and the oxide-containing layer functions as the oxygen source.

21. The method according to claim 16, further comprising:
etching away from the first main surface a silicon oxide layer created during the heating of the silicon substrate; and
etching away from the second main surface a part of the oxide-containing layer.

22. The method according to claim 16, further comprising:
after the application of the oxide-containing layer, diffusing into the first and second main surfaces a doping agent including at least one of boron, boron tribromide, phosphorus, and phosphorus oxychloride, the doping agent diffusing, during the heating of the silicon substrate, into the first main surface, and the oxide-containing layer functioning as a masking layer of the second main surface during the heating.

23. The method according to claim 22, further comprising:
etching away from at least one of the first main surface and the second main surface the doping agent-silicon compound layers created during the heating of the silicon substrate.

24. The method according to claim 16, further comprising:
before the application of the oxide-containing layer, applying to at least one of the first main surface and the second main surface a surface patterning.

25. The method according to claim 16, further comprising:
before the application of the oxide-containing layer, planarizing the second main surface.

26. The method according to claim 16, further comprising:
before the application of the oxide-containing layer, scrubbing at least one of the first main surface and the second main surface using HNO₃.

27. The method according to claim 16, further comprising:
diffusing or implanting boron or phosphorus into the second main surface for producing a back-surface-field (BSF) layer, which is activated by the heating of the silicon substrate.

28. The method according to claim 21, further comprising:
after the etching of the first and second main surfaces, applying a SiN antireflection layer to at least one of the first main surface and the oxide-containing layer of the second main surface.

29. The method according to claim 16, further comprising:
before the application of the oxide-containing layer, producing one or more holes through the silicon substrate for connecting the first main surface to the second main surface using a laser,

30. The method according to claim 16, further comprising, before the application of the oxide-containing layer:
diffusing into the first and second main surfaces a doping agent including at least one of boron, boron tribromide, phosphorus, and phosphorus oxychloride, the doping agent diffusing into the silicon substrate by the heating of the silicon substrate to form an emitter layer on the first main surface and an emitter layer on the second main surface;
etching away from at least one of the first main surface and the second main surface the doping agent-glass layers created by the heating of the silicon substrate;
applying a masking layer including SiN to the first main surface; and
removing the emitter layer of the second main surface by etching, the SiN layer functioning as a masking layer of the first main surface during the removing.
